(19) United States
(12) Patent Application Publication
(10) Pub. No.: US 2020/0219744 A1
(43) Pub. Date: Jul. 9, 2020

(54) SEMICONDUCTOR MANUFACTURING DEVICE

(71) Applicants: Seong Lae KIM, Hwaseong (KR); SUNRIN CO., LTD., Anseong (KR); BOYA CO., LTD., Hwaseong (KR)

(72) Inventors: Seong Lae KIM, Hwaseong (KR); Kwangwook LIM, Hwaseong (KR)

(21) Appl. No.: 16/648,438

(22) PCT Filed: Aug. 14, 2018
(86) PCT No.: PCT/KR2018/009361

§ 371 Date: Mar. 18, 2020

(30) Foreign Application Priority Data
Sep. 20, 2017 (KR) 10-2017-0121161

(51) Int. Cl. H01L 21/677

(52) U.S. Cl. CPC H01L 21/67739; H01L 21/67775

(57) ABSTRACT

A semiconductor manufacturing device, according to the present invention, comprises a load port unit, a substrate transfer unit, and a processing unit sequentially arranged along a transfer path of a semiconductor substrate, wherein the load port unit has a load door relatively movable with respect to the substrate transfer unit while being accommodated in the substrate transfer unit, and an air introduction path for connecting the inside and the outside of the substrate transfer unit under the load door; and the substrate transfer unit has a substrate processing module for communicating with the load port unit and the processing unit while limiting a processing space of the semiconductor substrate, and an air supply module positioned on the substrate processing module so as to supply dry, purified air to the substrate processing module.

### TECHNICAL FIELD

The present invention relates to the semiconductor manufacturing device for protecting a semiconductor substrate of a FOUP by inflowing an ambient gas used in a transfer path of a semiconductor substrate during a semiconductor manufacturing process into a FOUP (Front Opening Unified Pod).

### BACKGROUND

Generally, a semiconductor manufacturing factory has various kinds of semiconductor manufacturing devices. The semiconductor manufacturing device comprises, for function, a load port unit, a substrate transfer unit, and a process performing unit for performing a photo process, an etching process, or a deposition process, though there are some differences in external shape and internal structure depending on the unit process characteristics.

Here, the load port unit is positioned in front of the substrate transfer unit to seat a FOUP that receives a semiconductor substrate. The substrate transfer unit separates the semiconductor substrate from the FOUP using a robot arm and transfers the semiconductor substrate to the process performing unit.

The process performing unit supplies a semiconductor substrate from the substrate transfer unit and performs a photo process, an etching process, or a deposition process. Up to this point, the semiconductor manufacturing device has moved the semiconductor substrate along the transfer path from the FOUP to the process performing unit through the semiconductor transfer unit.

Hereafter, the semiconductor manufacturing device reverses the semiconductor substrate along the transfer path from the process performing unit to the FOUP through the semiconductor transfer unit, thereby inserting the semiconductor substrate into the FOUP. While the semiconductor substrate is moving along the transfer path, the semiconductor substrate is surrounded by nitrogen gas in the semiconductor transfer unit and thereby inserted into the FOUP and the process performing unit.

On the other hand, the semiconductor manufacturing device in the above is disclosed in Korean Patent Registration No. 10-1768596 as a prior art. The semiconductor manufacturing device encloses a wafer placed in the FOUP or a wafer placed in the wafer transfer chamber through nitrogen gas by inflowing nitrogen gas into the load port and the wafer transfer chamber.

The nitrogen gas interferes with the reaction of the wafer with contaminants present in the interior of the FOUP or in the interior of the wafer transfer chamber, and the reaction of the wafer adjacent with the gas containing the fluorine remaining on one specific wafer inside the FOUP during the semiconductor manufacturing process.

However, when the semiconductor manufacturing device uses nitrogen gas as an ambient gas in the FOUP and wafer transfer chamber, because the nitrogen gas is specially manufactured and ordered at an expensive cost, the semiconductor device is partially lost toward the outside of the semiconductor manufacturing device when the FOUP and the load port are detached/attached or when the FOUP and the wafer transfer chamber are detached/attached, thereby raising the manufacturing cost of a semiconductor device.

Furthermore, when the semiconductor manufacturing device accommodates a plurality of load ports in the wafer transfer chamber, the load port and the wafer transfer chamber continuously circulate the nitrogen gas during the semiconductor manufacturing process, so that the partial disposal amount of the nitrogen gas cumulatively increases in time and thereby causes the operator to suffocate.

Furthermore, the semiconductor manufacturing device uses a fan unit to blow nitrogen gas into the wafer transfer chamber. The fan unit additionally requires a fan monitor product associated with the fan during its service life, which causes the wafer to be lost due to the infiltration of contaminants to the inside from the outside of the wafer transfer chamber.

### SUMMARY OF THE INVENTION

The present invention is devised to solve the conventional problems, and the goal of the present invention is to provide a semiconductor manufacturing device which can uses replaceable gas instead of nitrogen gas and reduces manufacturing cost of a semiconductor device, thereby minimizing the influence of moisture adsorbed in the semiconductor manufacturing process environment by using replace gas instead of nitrogen gas, making the environment of semiconductor manufacturing process improved, minimizing the risk of suffocation by workers performing semiconductor manufacturing processes by using replaceable gas instead of nitrogen gas, and thus, reducing component management items by using a replaceable unit instead of a pan unit, and maintaining a constant yield of a semiconductor substrate.

A semiconductor manufacturing device according to the present invention comprises a load port unit, a substrate transfer unit, and a process performing unit which are sequentially arranged along a transfer path of a semiconductor substrate, wherein the load port unit is received to the substrate transfer unit and is equipped with a load door movable relative to the substrate transfer unit and an air introduction flow path connecting the inside and the outside of the substrate transfer unit under the load door, wherein the substrate transfer unit has a substrate processing module limiting a process space of the semiconductor substrate and connected with the road port unit and the process performing unit; and an air supplying module supplying dry purified air to the substrate processing module, characterized in that when the FOUP receiving the semiconductor substrate is placed in front of the load door on the air introduction flow path of the load port unit, while exposing the inside of the substrate processing module by opening the load door, the air supply module passes the dry purified air the substrate processing module and the load port unit and the FOUP in order and transfers the dry purified air toward the substrate processing module from the FOUP through an opening corresponding to the load door.

The load port unit includes a base portion, a placement portion and a column portion, wherein the base portion has a shelf surface that leans on the column portion in the form of a shelf and is perpendicular to the rod door, wherein the mount portion is parallelly placed with the shelf surface on the shelf surface of the base portion and fixed to the shelf surface, wherein the column portion supports the base portion and is perpendicular to the shelf surface around an edge of the shelf surface, and rises higher than the shelf surface, so as to have the load door at a higher level than the shelf surface.

The base portion, the placement portion and the column portion may have at least one air introduction flow path.

The placement portion may include a plurality of positioning pins for adjusting the position of the FOUP and a lock ring for interfering with the movement of the FOUP.

The FOUP has air-receiving holes of the same number with air introduction flow path on one side surface thereof, wherein the FOUP is closely contacted to the placement portion through a plurality of the poisoning pins and the lock ring when the FOUP is seated in front of the rod door of the load port unit, so as to align the air-receiving hole with the air introduction flow path.

The substrate processing module may include a substrate transfer device including a multi joint robot arm, wherein the multi joint robot arm may be inserted into the gate of the load port unit and the gate of the process performing unit through the substrate transfer device.

The air supply module includes an air injection part which is positioned directly above the substrate processing module to generate dry air from humid compressed air, wherein the air injection part includes a control unit electrically connected to each other, an humified compressed air supply section, an air regeneration section, an air storage tank, and a mass flow controller, wherein the control unit electrically controls driving of the humid compressed air supply section, the air regeneration section, the air storage tank and the mass flow controller.

The humid compressed air supply unit may include less than 1 part by weight of moisture relative to 100 parts by weight of the humid compressed air and may transmit the humid compressed air to the air regeneration unit through a first control signal of the control unit.

The air regeneration section, while receiving the humid compressed air from the humid compressed air supply unit through the second control signal of the control unit and generating the dry air from the humid compressed air, can transfer the dry air at least one of the air storage tank and the humid compressed air supply section, wherein the dry air can have the same dew point as nitrogen.

The air regeneration unit includes a housing of a container-shape with an opening at one side, a housing lid defining a gas inlet and a gas outlet on the housing, an induction pipe supported by at least one of the housing and the housing lid, a plurality of hollow fibers, an orifice, and a gas discharge tube.

The housing lid communicates with humid compressed air supply unit through the gas inlet, with a plurality of the hollow fibers through the gas outlet, and with the mass flow controller through the gas outlet, wherein the housing lid is spaced from the gas inlet and the gas outlet so as to suspend a plurality of the hollow fibers in a ‘U’-shape, and surrounds the plurality of hollow fibers through a predetermined space and is in a close contact to each hollow fiber to limit the gas outlet.

Wherein the housing lid includes a first housing lid and a second housing lid, wherein the first housing lid and the second housing lid surround the orifice surrounding the plurality of hollow fibers, and the second housing lid has the gas inlet and the gas outlet.

The induction pipe is secured to the housing lid while enclosing the plurality of hollow fibers below the housing lid so as to be received in the housing and to communicate with the space of the housing lid.

The plurality of the hollow fibers are received in the induction pipe and pass through the housing lid and are exposed to the gas inlet and the gas outlet, and the humid compressed air is supplied from the humid compressed air supply unit through the gas inlet, wherein the dry air is generated at the gas outlet by discharging moisture from the hollow through fibers in the compressed air toward the induction pipe, and the housing lid discharges the dry air through the orifice to the mass flow controller or to transfer the dry air towards the orifice, the air storage tank, and the mass flow controller.

The orifice is placed inside the housing lid and communicates with the gas outlet while facing the plurality of hollow fibers through the space of the housing lid, and the dry air is supplied from the gas outlet and delivers the dry air to the induction pipe through the space of the housing lid to push the moisture through the drying air, wherein the speed of the dry air is faster than the speed of the humid compressed air after passing through the orifice and the pressure of the dry air is lower than the pressure of the humid compressed air after passing through the orifice.

The gas discharge pipe passes through the housing and the housing lid from the outside of the housing in order, faces a plurality of the hollow fibers through the space of the housing lid, and then discharges the moisture, which is supplied with the moisture through the induction pipe and the housing lid, to the outside of the housing through the housing lid.

An opening and closing valve is included between the air regeneration unit and the air storage tank. While the opening of the opening and closing valve is opening, in accordance with the third control signal of the control unit, the air storage tank is supplied with the dry air from the air regeneration unit and stores the dry air to an inner space. While the opening of the opening and closing valve is closing, in accordance with the fourth control signal of the control unit, the air storage tank transfers the dry air to the mass flow controller when the air regeneration unit is out of order.

The air supply module includes a pressure sensor located on the load door under the air injection part and electrically connected to the control unit; and an air filter part positioned immediately below the air injection part, wherein the pressure sensor can measure an internal pressure value of the substrate processing module and transfer the internal pressure value to the control unit through an electric signal.

The mass flow controller, while adjusting a flow rate of the dry air according to a fifth control signal of the control unit based on the internal pressure value of the substrate processing module after receiving the dry air from the air regeneration unit or the air storage tank, transfers an adjusted dry air to the air filter part, wherein the air filter part is supplied with the dry air adjusted by a filter and adsorbs impurities of the adjusted dry air with the filter to generate the dry purified air.

The load port unit, the substrate transfer unit, and the process performing unit are placed on a floor of a semiconductor manufacturing factory, wherein the semiconductor manufacturing device further comprises a ventilation unit below the floor of the semiconductor manufacturing factory, wherein the ventilation unit, connected to the substrate processing module through an air outlet pipe, receives the dry purified air from the substrate processing module and discharge the dry purified air toward the atmosphere, wherein the process performing unit is supplied with a semiconductor substrate at the substrate processing module through a multi joint robot arm to perform a semiconductor manufacturing process at the semiconductor substrate.

The present invention is characterized in that a load port unit, a substrate transfer unit and a process performing unit are sequentially provided along a transfer path of a semiconductor substrate and the dry purified air is circulated in place of the nitrogen gas in the load port unit and the substrate transfer unit, thereby being able to reduce the cost of semiconductor manufacturing by using dry purified air at a lower cost than nitrogen gas.

It is possible that the present invention, by circulating a dry purified air in place of nitrogen gas from FOUP, starting from the substrate transfer unit and then passing through the load port unit and FOUP sequentially, toward the substrate transfer unit, the dry purified air having the same dew point as nitrogen gas is used, can improve the environment of the semiconductor manufacturing process by minimizing the effect of moisture absorbed onto the semiconductor substrate, e.g. production of manufacturing process by-products or natural oxide films.

It is possible that the present invention, because the load port unit and the substrate transfer unit and the process performing unit are provided, and oxygen is included in the dry purified air while circulating the dry purified air instead of nitrogen gas, can have the same proportion of the oxygen and the nitrogen gas therein as the oxygen and the nitrogen in the atmosphere when the FOUP and the load port unit are attached/detached and when the FOUP and the substrate transfer unit are attached/detached, no matter of the cumulative increase of the dry purified air, thereby minimizing the risk of suffocation of workers at the semiconductor manufacturing process.

The present invention is provided with a substrate processing module and an air supply module that are sequentially stacked on a substrate transfer unit, and uses a humid compressed air supply unit and an air regeneration unit in place of a fan unit in an air supply module and thereby generates the dry air from the humid compressed air, and continuously generates the dry purified air by passing the dry air through the air filter unit, so as to be able to reduce the items of fan-related part management.

The present invention is provided with the air supply module which uses humid compressed air supply unit, an air regeneration unit, and a filter unit therein in place of a fan unit to generate dry purified air and supplies the dry purified air to the substrate processing module, or is provided with an air storage tank at an air supply module for passing the dry air of the air storage tank through the air filter unit and supplying dry purified air to the substrate processing module in an emergency when the air regeneration unit is out of order, so that it is possible to maintain the yielding rate of semiconductor substrate constants due to no contaminant in the processing module and the FOUP.

### BRIEF DESCRIPTION OF THE DRAWINGS

FIG. 1 is a perspective view schematically illustrating a semiconductor manufacturing device according to the present invention.

FIG. 2 is a partial perspective view illustrating, in detail, the load port unit of FIG. 1 according to the present invention.

FIG. 3 is a cross-sectional view schematically illustrating the semiconductor manufacturing device of FIG. 1 according to the present invention.

FIG. 4 is a block diagram schematically illustrating an air supply module in the semiconductor manufacturing device of FIG. 3 according to the present invention.

FIG. 5 is a cross-sectional view illustrating the air regeneration unit in the air supply module of FIG. 4 according to the present invention.

FIG. 6 is a schematic view illustrating a hollow fiber partially cut in the air regeneration unit of FIG. 5 according to the present invention.

FIG. 7 is a schematic view for illustrating an operation method of the semiconductor manufacturing device of FIG. 1 according to the present invention.

### DETAILED DESCRIPTION OF PREFERRED EMBODIMENTS

Hereinafter, preferred embodiment(s) of the present invention will be described in detail with reference to the accompanying drawings so that an ordinary person skilled in the art can easily carry out the present invention.

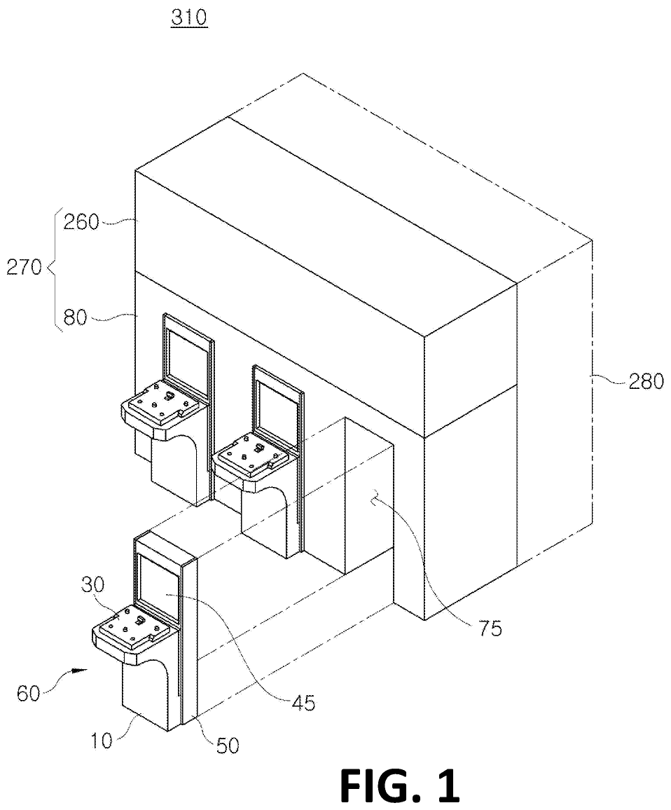

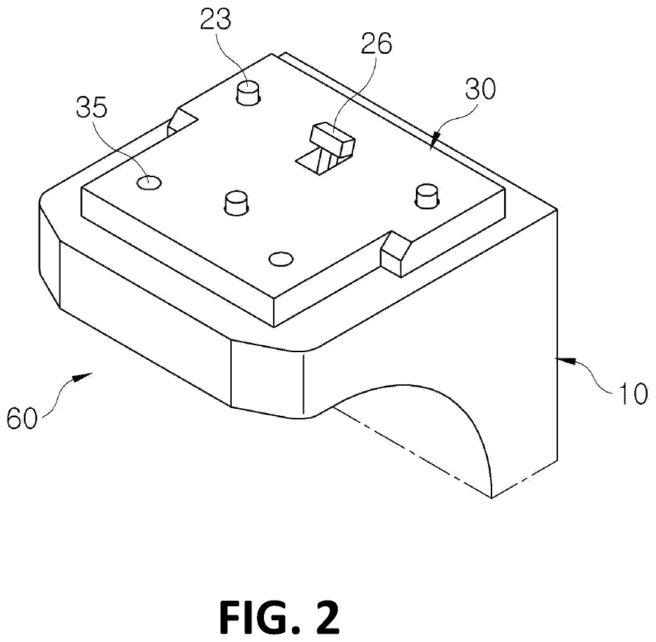

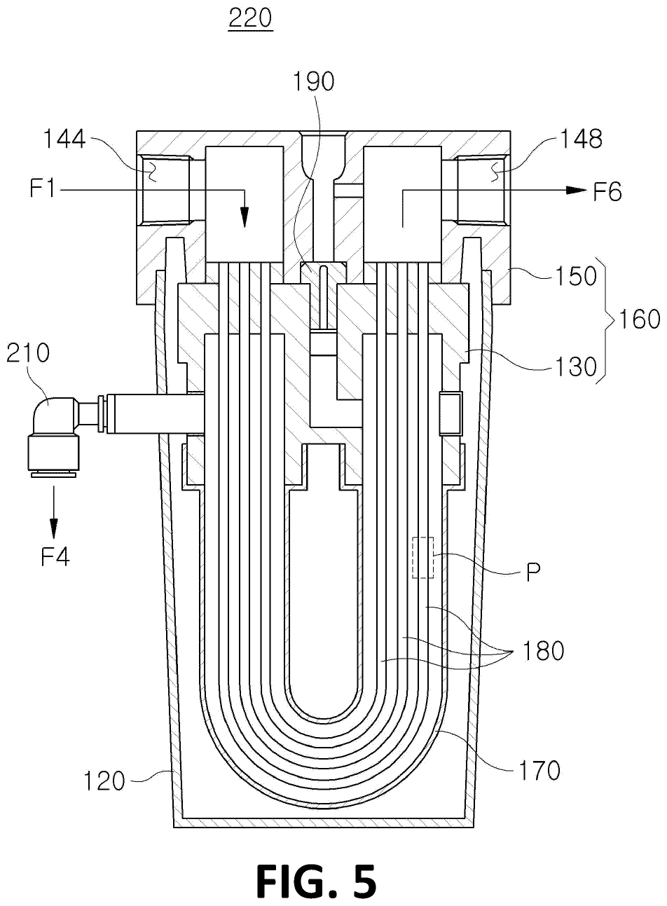

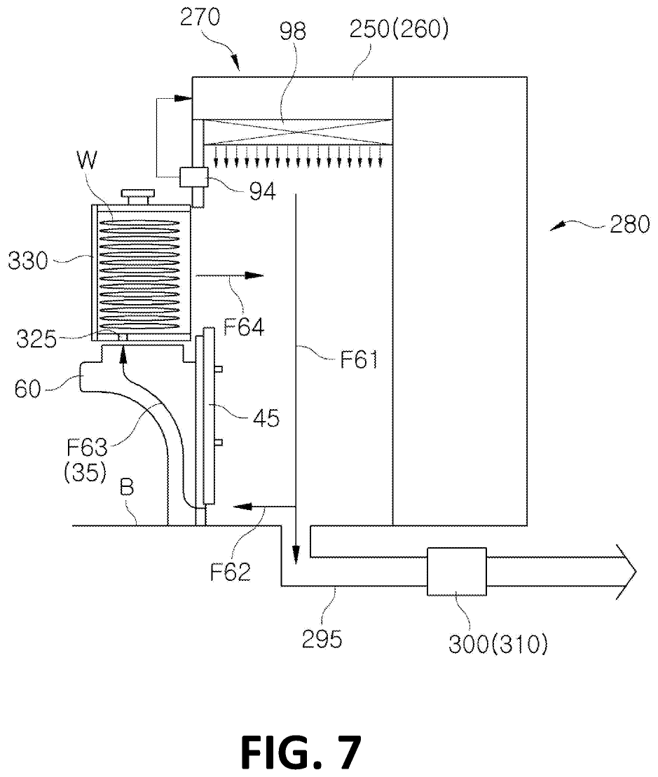

Referring to FIGS. 1 to 6, a semiconductor manufacturing device 310 according to the present invention includes a load port unit 60 sequentially arranged along a transfer path of a semiconductor substrate (W in FIG. 7), a substrate transfer unit 270 and a process performing unit 280. Herein, the load port unit 60 is received to the substrate transfer unit 270 while seating a FOUP 330 that receives a semiconductor substrate, as illustrated in FIG. 7.

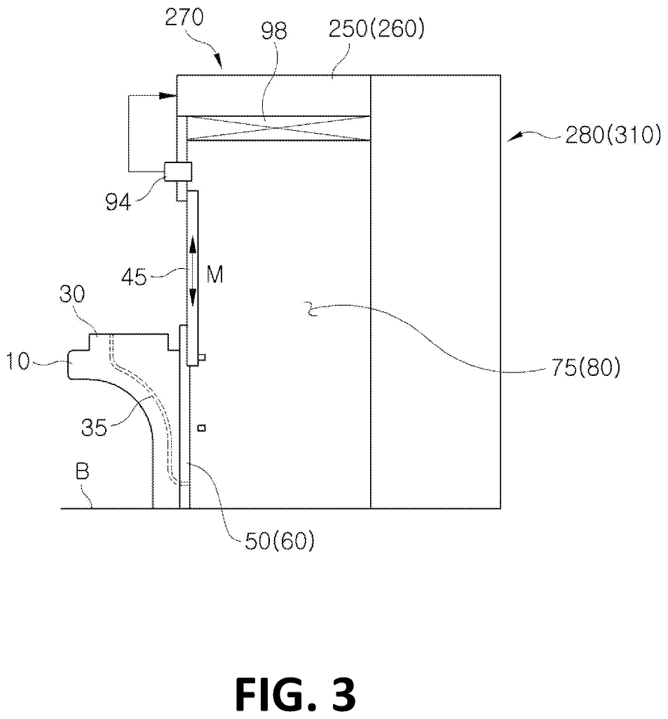

The load port unit 60 includes a load door 45 that is relatively movable with respect to the substrate transfer unit 270 and an air introduction flow paths (35 in FIG. 3) that connects the inside and the outside of the substrate transfer unit 270 under the load door 45. More specifically, the load port unit 60 includes a base portion 10, a mount portion 30, and a column portion 50.

The base portion 10 has a large flat shelf surface (not illustrated in the drawings) that is perpendicular to the load door 45 by leaning against the column portion 50 in a shelf form. The mount portion 30 is positioned on the shelf surface of the base portion 10 in parallel with the shelf surface and fixed to the shelf surface. The mount portion 30 includes a plurality of positioning pins 23 for adjusting the position of the FOUP 330 and a lock ring 26 for interfering with the movement of the FOUP 330.

The column portion 50 supports the base portion 10 and is perpendicular to the shelf surface around the edge of the shelf surface and rises higher than the shelf surface to have the load door 45 at a higher level than the shelf surface. Herein, the base portion 10, the mount portion 30, and the column portion 50 have at least one air introduction flow path 35.

The substrate transfer unit 270 includes a substrate processing module 80 that communicates with the load port unit 60 and the process performing unit 280 while limiting a process space of the semiconductor substrate (W), and an air supply module 260 which supplies dry purified air to the substrate processing module 80.

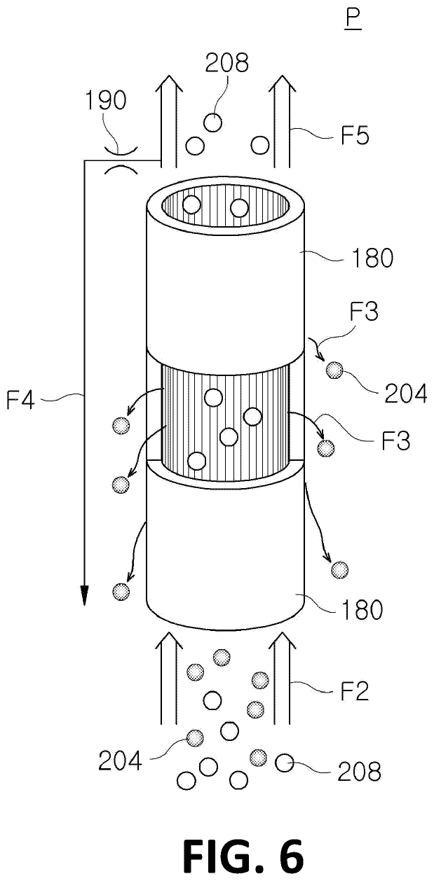

The substrate processing module 80 has a substrate transfer device (not shown in the drawings) having a multi joint robot arm and can insert a multi joint robot arm to a gate of the load port unit 80 and a gate of the process performing unit 280 through a substrate transfer device. The air supply module 260 includes an air injection part 250 positioned directly above the substrate processing module 80 to generate dry air 208 in FIG. 6 from humid compressed air.

The dry 208 has the same dew point (60° C.) as nitrogen gas. The air injection part 250 includes a control unit 100 electrically connected to each other, an humified compressed air supply unit 110, an air regeneration section 220, an air storage tank 230, and a mass flow controller 240.

The control unit 100 electrically controls the operation of the humid compressed air supply unit 110, the air regeneration unit 220, the air storage tank 230, and the mass flow controller 240. The humid compressed air supply unit 110 includes humidified air of less than 1 part by weight with respect to 100 parts by weight of humid compressed air and transfers humid compressed air to the air regeneration unit 220 through the first control signal of the control unit 100.

The air regeneration unit 220 receives the humid compressed air from the humid compressed air supply unit 110 through the second control signal of the control unit 100 and generates the dry air 208 from the humid compressed air to transfer the dry air 208 to at least one of the air storage tank 230 and the mass flow controller 240.

More specifically, the air regeneration unit 220 includes a housing 120 having a container shape with an opening at one side, a housing lid 160 that limits a gas inlet 144 and a gas outlet 148 on the housing 120, and an induction pipe 170 supported by at least one of the housing 120 and the housing lid 160, a plurality of hollow fibers 180, an orifice 190, and a gas discharge pipe 210.

The housing lid 160 communicates with a humid compressed air supply unit 110 through the gas inlet 144, with a plurality of hollow fibers 180 through a gas outlet 148, and with a mass controller 240 through the gas outlet 148, wherein the housing lid 160 can be spaced from the gas inlet 144 and the gas outlet 148 so as to suspend a plurality of the hollow fibers 180 in a ‘U’-shape, and surround a plurality of the hollow fibers 180 through a predetermined space and be in a close contact to each hollow fiber 180 to limit the gas outlet 148.

Herein, the housing lid 160 includes a first housing lid 130 and a second housing lid 150. The first housing lid 130 and the second housing lid 150 surround an orifice 190 while surrounding a plurality of the hollow fibers 180. The second housing lid 150 has the gas inlet 144 and the gas outlet 148.

The induction pipe 170 is fixed to the housing lid 160 so as to surround a plurality of the hollow fibers 180 under the housing lid 160 so as to be accommodated in the housing 120 and communicate with a space of the housing lid 160 do. The plurality of hollow fibers 180 are accommodated in the induction pipe 170 and are exposed to the gas inlet 144 and the gas outlet 148 through the housing lid 160.

Furthermore, a plurality of the hollow fibers 180 are supplied with the humid compressed air 204, 208 along the first and the second flow lines (F1, F2) from the humid compressed air supply unit 110 through the gas inlet 144, and discharge moisture 204 along the third flow line (F3) from a hollow through a fiber in the middle of the humid compressed air 204, 208, and generate dry air 208 at the gas outlet 148 along the fifth flow (F5).

Herein, the housing lid 160 transfer the dry air 208 through the gas outlet 148 to the orifice 190 and the mass flow controller 240 along the sixth flow line (F6), or transfer the dry air 208 to the orifice 190, the air storage tank 220 and the mass flow controller 240 along the sixth flow line (F6).

The orifice 190 is placed inside the housing lid 160 and communicates with the gas outlet 148 while facing the plurality of hollow fibers 180 through the space of the housing lid 160, and is supplied the dry air 208 from the gas outlet 148 to transfer the dry air 208 to the induction pipe 170 through the space of the housing lid 160 to push the moisture 204 away through the drying air 208.

The velocity of the dry air 208 is faster than the velocity of the humid compressed air 204, 208 after passing the orifice 190 along the fourth flow line (F4). The pressure of the dry air 208 is lower than the pressure of the humid compressed air 204, 208 after passing through the orifice 190. The gas discharge tube 210 passes through the housing 120 and the housing lid 160 in order from the outside of the housing 120 and faces a plurality of the hollow fibers 180 through the space of the housing lid 160.

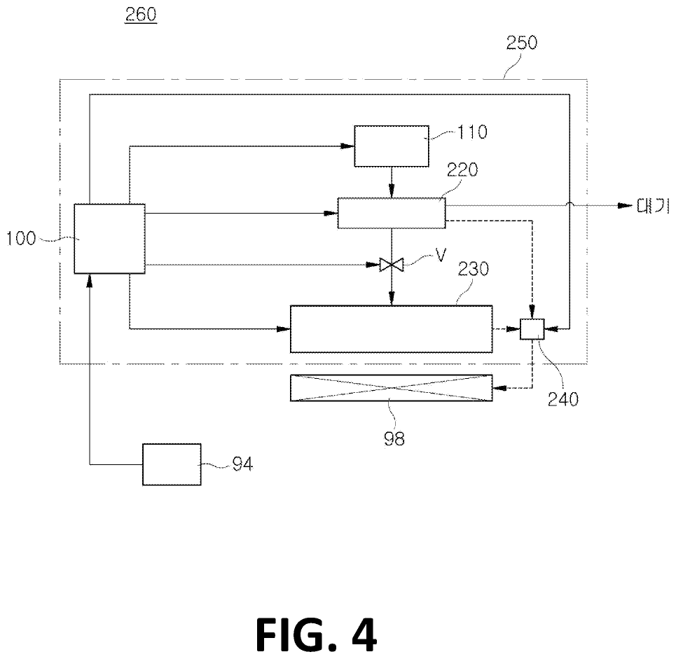

The gas discharge pipe 210, therefore, is supplied with the moisture 204 through the induction pipe 170 and the housing lid 160 and discharges the moisture 204 toward the outside of the housing 120 through the housing lid 160 along the fourth flow line (F4). For example, the gas discharge pipe 210 discharges the moisture 204 along the fourth flow line (F4) toward the atmosphere as illustrated in FIG. 4.

Meanwhile, an opening and closing valve (V in FIG. 4) is provided between the air regeneration unit 220 and the air storage tank 230. According to the third control signal of the control unit 100, the air storage tank 230 receives the dry air 208 from the air regeneration unit 220 while the opening and closing valve (V) is opened and stores the dry air 208 to the inner space thereof.

According to the fourth control signal of the control unit 100, while the opening and closing valve (V) is closed, the air storage tank 230 transfers the dry air stored to a mass flow controller 240 when the air regeneration unit 220 is out of order. The air supply module 260 includes a pressure sensor 94 positioned on the load door 45 under the air injection part 250 and electrically connected to the control unit 100, and further includes an air filter portion 98 to be placed directly below an air injection part 250 as illustrated in FIG. 4.

The pressure sensor 94 measures an internal pressure value of the substrate processing module 80 and transfers the internal pressure value to the control unit 100 through an electric signal. The mass flow controller 240 receives the dry air 208 from the air regeneration unit 220 or the air storage tank 230 and controls the flowing amount of the dry air 208 according to the fifth control signal based on the internal pressure of the substrate processing module 80, so as to transfer the adjusted dry air to the air filter part 98.

The air filter unit 98 is supplied with the dry air adjusted through a filter and generates dry purified air by adsorbing impurities in the adjusted dry air. The dry purified air has the same ratio of nitrogen and oxygen as the air in the atmosphere. The load port unit 60, the substrate transfer unit 270, and the process performing unit 280 are placed on the bottom (B) of the semiconductor manufacturing plant. The semiconductor manufacturing device 310 further includes a ventilation unit 300 (illustrated in FIG. 7) below the bottom (B) of the semiconductor manufacturing factory.

The ventilation unit 300 communicates with the substrate processing module 80 through an air outlet pipe 295 and receives dry purified air from the substrate processing module 80 along the flow line (illustrated as F61 in FIG. 7) and discharge the dry purified air toward the atmosphere. The process performing unit 280 is supplied with a semiconductor substrate (W) through the multi joint robot arm of the substrate transfer device at the substrate processing module 80 and performs a semiconductor manufacturing process on the semiconductor substrate (W).

FIG. 7 is a schematic view for explaining an operation method of the semiconductor manufacturing device of FIG. 1.

Referring to FIG. 7, in the semiconductor manufacturing device 310, the load port unit 60 may seat a FOUP 330 receiving on at least one semiconductor substrate (W). Herein, the FOUP 330 may have the same number of air-receiving holes 325 as the air introduction flow paths 35 of the rod port unit 60 on one side.

When the FOUP 330 is seated in front of the load door 45 of the load port unit 60, while the load door 45 is opened, the FOUP can be brought into close contact with the mount portion 30 through a plurality of positioning pins 23 and a lock ring 26 at the mount portion 30 and align the air-receiving holes with the air introduction flow path 35.

Subsequently, at the substrate transfer unit 270, the air supply module 260 can supply dry purified air to the substrate processing module 80 by using the pressure sensor 94, the air filter unit 98, and the air injection part 250. The dry purified air includes nitrogen gas and oxygen and can be utilized as ambient gas of the substrate processing module 80. The dry purified air can be filled into the substrate processing module 80 along the main flow line (F61).

When the FOUP 330 is seated in front of the rod door 45 on the air introduction flow path 35 of the rod port unit 60, while the inside of the substrate processing module 80 is exposed into the inside of the FOUP by opening of the load door 45, the air supply module 260 passes the dry purified air to the substrate processing module 80, the load port unit 60 and the FOUP 330 along the branch flow lines F62 and F63 Through the opening corresponding to the load door 45, the dry purified air can be transferred along the branch flow line F64 from the FOUP 330 to the substrate processing module 80.

Herein, while being circulated in the substrate processing module 80, the load port unit 60 and the FOUP 330, the clean purified air reaches a ventilation unit 300 along the main flow line (F61) through the air outlet pipe 295 placed at the bottom (B) of the semiconductor manufacturing plant and is then discharged to the atmosphere.

1. A semiconductor manufacturing device comprising:
a load port unit, a substrate transfer unit, and a process performing unit which are sequentially arranged along a transfer path of a semiconductor substrate,
wherein the load port unit is received to the substrate transfer unit and is equipped with a load door movable relative to the substrate transfer unit and an air introduction flow path connecting the inside and the outside of the substrate transfer unit below the load door,
wherein the substrate transfer unit has a substrate processing module limiting a process space of the semiconductor substrate and connected with the load port unit and the process performing unit; and an air supplying module supplying dry purified air to the substrate processing module, characterized in that when a FOUP receiving the semiconductor substrate is placed in front of the load door on the air introduction flow path of the load port unit, while exposing the inside of the substrate processing module by opening the load door, the air supply module passes the dry purified air the substrate processing module and the load port unit and the FOUP in order and transfers the dry purified air toward the substrate processing module from the FOUP through an opening corresponding to the load door.

2. The semiconductor manufacturing device of claim 1,
wherein the load port unit comprises a base portion, a placement portion and a column portion,
wherein the base portion has a shelf surface that leans on the column portion in the form of a shelf and is perpendicular to a rod door, wherein a mount portion is parallelly placed with the shelf surface on the shelf surface of the base portion and fixed to the shelf surface, wherein the column portion supports the base portion and is perpendicular to the shelf surface around an edge of the shelf surface, and rises higher than the shelf surface, so as to have the load door at a higher level than the shelf surface.

3. The semiconductor manufacturing device of claim 2,
wherein the base portion, the placement portion and the column portion may have at least one air introduction flow path.

4. The semiconductor manufacturing device of claim 2,
wherein the placement portion may include a plurality of positioning pins for adjusting the position of the FOUP and a lock ring for interfering with the movement of the FOUP.

5. The semiconductor manufacturing device of claim 4,
wherein the FOUP has air-receiving holes of the same number with air introduction flow path on one side surface thereof, wherein the FOUP is closely contacted to the placement portion through a plurality of the positioning pins and the lock ring when the FOUP is seated in front of the rod door of the load port unit, so as to align the air-receiving hole with the air introduction flow path.

6. The semiconductor manufacturing device of claim 1,
wherein the substrate processing module may include a substrate transfer device including a multi joint robot arm, wherein the multi joint robot arm may be inserted into a gate of the load port unit and a gate of the process performing unit through the substrate transfer device.

7. The semiconductor manufacturing device of claim 1,
wherein the air supply module includes an air injection part which is positioned directly above the substrate processing module to generate dry air from humid compressed air, wherein the air injection part includes a control unit electrically connected to each other, a humified compressed air supply section, an air regeneration section, an air storage tank, and a mass flow controller, wherein the control unit electrically controls driving of the humid compressed air supply section, the air regeneration section, the air storage tank and the mass flow controller.

8. The semiconductor manufacturing device of claim 7,
wherein the humid compressed air supply unit may include less than 1 part by weight of moisture relative to 100 parts by weight of the humid compressed air and may transmit the humid compressed air to the air regeneration unit through a first control signal of the control unit.

9. The semiconductor manufacturing device of claim 7,
wherein the air regeneration section, while receiving the humid compressed air from the humid compressed air supply unit through a second control signal of the control unit and generating the dry air from the humid compressed air, transfers the dry air to at least one of: the air storage tank and the humid compressed air supply section, wherein the dry air has the same dew point as nitrogen.

10. The semiconductor manufacturing device of claim 7,
wherein the air regeneration unit includes a housing of a container-shape with an opening at one side, a housing lid defining a gas inlet and a gas outlet on the housing, an induction pipe supported by at least one of the housing and the housing lid, a plurality of hollow fibers, an orifice, and a gas discharge tube.

11. The semiconductor manufacturing device of claim 10,
wherein the housing lid communicates with humid compressed air supply unit through the gas inlet, with a plurality of the hollow fibers through the gas outlet, and with the mass flow controller through the gas outlet, wherein the housing lid is spaced from the gas inlet and the gas outlet so as to suspend a plurality of the hollow fibers in a ‘U’-shape, and surrounds the plurality of hollow fibers through a predetermined space and is in a close contact to each hollow fiber to limit the gas outlet.

12. The semiconductor manufacturing device of claim 11,
wherein the housing lid includes a first housing lid and a second housing lid, wherein the first housing lid and the second housing lid surround the orifice surrounding the plurality of hollow fibers, and the second housing lid has the gas inlet and the gas outlet.

13. The semiconductor manufacturing device of claim 11,
wherein the induction pipe is secured to the housing lid while enclosing the plurality of hollow fibers below the housing lid so as to be received in the housing and to communicate with the space of the housing lid.

14. The semiconductor manufacturing device of claim 13,
wherein the plurality of the hollow fibers are received in the induction pipe and pass through the housing lid and are exposed to the gas inlet and the gas outlet, and the humid compressed air is supplied from the humid compressed air supply unit through the gas inlet, wherein the dry air is generated at the gas outlet by discharging moisture from the hollow through fibers in the compressed air toward the induction pipe, and the housing lid discharges the dry air through the orifice to the mass flow controller or to transfer the dry air towards the orifice, the air storage tank, and the mass flow controller.

15. The semiconductor manufacturing device of claim 14,
wherein the orifice is placed inside the housing lid and communicates with the gas outlet while facing the plurality of hollow fibers through the space of the housing lid, and the dry air is supplied from the gas outlet and delivers the dry air to the induction pipe through the space of the housing lid to push the moisture through the drying air, wherein the speed of the dry air is faster than the speed of the humid compressed air after passing through the orifice and the pressure of the dry air is lower than the pressure of the humid compressed air after passing through the orifice.

16. The semiconductor manufacturing device of claim 10,
wherein a gas discharge pipe passes through the housing and the housing lid from the outside of the housing in order, faces a plurality of the hollow fibers through the space of the housing lid, and then discharges the moisture, which is supplied with the moisture through the induction pipe and the housing lid, to the outside of the housing through the housing lid.

17. The semiconductor manufacturing device of claim 9,
wherein an opening and closing valve is included between the air regeneration unit and the air storage tank. While the opening of the opening and closing valve is opening, in accordance with the third control signal of the control unit, the air storage tank is supplied with the dry air from the air regeneration unit and stores the dry air to an inner space. While the opening of the opening and closing valve is closing, in accordance with the fourth control signal of the control unit, the air storage tank transfers the dry air to the mass flow controller when the air regeneration unit is out of order.

18. The semiconductor manufacturing device of claim 17,
wherein the air supply module includes a pressure sensor located on the load door under the air injection part and electrically connected to the control unit; and an air filter part positioned immediately below the air injection part, wherein the pressure sensor can measure an internal pressure value of the substrate processing module and transfer the internal pressure value to the control unit through an electric signal.

19. The semiconductor manufacturing device of claim 18,
wherein the mass flow controller, while adjusting a flow rate of the dry air according to a fifth control signal of the control unit based on the internal pressure value of the substrate processing module after receiving the dry air from the air regeneration unit or the air storage tank, transfers an adjusted dry air to the air filter part, wherein the air filter part is supplied with the dry air adjusted by a filter and adsorbs impurities of the adjusted dry air with the filter to generate the dry purified air.

20. The semiconductor manufacturing device of claim 1,
wherein the load port unit, the substrate transfer unit, and the process performing unit are placed on a floor of a semiconductor manufacturing factory, wherein the semiconductor manufacturing device further comprises a ventilation unit below the floor of the semiconductor manufacturing factory, wherein the ventilation unit, connected to the substrate processing module through an air outlet pipe, receives the dry purified air from the substrate processing module and discharge the dry purified air toward the atmosphere, wherein the process performing unit is supplied with a semiconductor substrate at the substrate processing module through a multi joint robot arm to perform a semiconductor manufacturing process at the semiconductor substrate.
